(19) United States
(12) Patent Application Publication
(10) Pub. No.: US 2018/0096867 A1
(43) Pub. Date: Apr. 5, 2018

(54) HEATING APPARATUS WITH CONTROLLED THERMAL CONTACT

(71) Applicant: Momentive Performance Materials Inc., Waterford, NY (US)

(72) Inventor: Zhong-Hao Lu, Twinsburg, OH (US)

(21) Appl. No.: 15/281,605

(22) Filed: Sep. 30, 2016

(51) Int. Cl. H01L 21/67; B23P 15/26

(52) U.S. Cl. CPC H01L 21/67103; B23P 15/26

(57) ABSTRACT

A heater assembly is provided having a configuration to promote more uniform heating and temperature distribution to the heating surface. A heater assembly as disclosed herein comprises a bottom plate comprising a heating element and a top plate having an upper surface for heating a substrate and a lower surface that contacts the bottom plate. The upper plate is provide such that the lower surface has a surface topography such that the contact points between the upper plate and the lower plate.

### FIELD OF INVENTION

The present invention relates to a heater assembly. In particular, the present invention relates to a heater assembly configuration suitable for a wide variety of applications including, but not limited to, heating a semiconductor wafer in a semiconductor processing device.

### BACKGROUND

Many semiconductor processes are typically performed in a vacuum environment, i.e., a sealed chamber containing an assembly for supporting the wafer substrate(s) disposed therein. In a semiconductor process, a heating apparatus typically includes a ceramic support that may have electrodes disposed therein to heat the support, and additionally may have electrodes that electrostatically hold the wafer or substrate against the ceramic support, i.e., electrostatic chuck or ESC (also sometimes called susceptors). A semiconductor device fabrication process can take place in the chamber, including deposition, etching, implantation, oxidation, etc. An example of a deposition process is a physical vapor deposition (PVD) process, known as sputter deposition, in which a target generally comprised of a material to be deposited on the wafer substrate is supported above the substrate, typically fastened to a top of the chamber. Plasma is formed from a gas such as argon supplied between the substrate and the target. The target is biased causing ions within the plasma to be accelerated toward the target. The ions of the plasma interact with the target material, and cause atoms of the material to be sputtered off, travel through the chamber toward the wafer, and redeposit on the surface of a semiconductor wafer that is being processed into integrated circuits (IC's). Other deposition processes may include, but are not limited to, plasma enhanced chemical vapor deposition (PECVD), high density plasma chemical vapor deposition (HDP-CVD), low pressure chemical vapor deposition (LPCVD), sub-atmospheric pressure chemical vapor deposition (SACVD), metal organic chemical vapor deposition (MOCVD), molecular beam evaporation (MBE), etc.

In some of the above processes it is desirable to heat the wafer by heating the support. The chemical reaction rate of the materials being deposited, etched, implanted, etc, is controlled to some degree by the temperature of the wafer. Undesirable unevenness in deposition, etching, implantation, etc., over a face of the wafer can easily result if the temperature of the wafer across its area varies too much. In most cases, it is highly desirable that deposition, etching, implantation be uniform to a nearly perfect degree since otherwise the IC's being fabricated at various locations on the wafer will have electronic characteristics that deviate from the norm more than is desirable.

Molded aspheric lenses are commonly used in consumer cameras, camera phones, and CD players due to their low cost and good performance. They are also commonly used for laser diode collimation, and for coupling light into and out of optical fibers. In molding a glass mass to make an aspheric lens, a pair of metal or ceramic molds are used. In this process, a plurality of heaters are used to heat up the molds until the glass mass is softened with the temperature of the glass mass can reach up to 600° C. As with a semiconductor-processing chamber, it is desirable that the molds be uniformly heated and their temperatures be closely controlled.

Various attempts have been tried to control the temperature of a substrate such as a wafer or molded lenses. In one example of a semiconductor process, an inert coolant gas (such as helium or argon) is admitted at a single pressure within a single thin space between the bottom of the wafer and the top of the ESC which holds the wafer. This approach is referred to as backside gas cooling. Yet another way of dealing with the need for zone cooling is to use coolant gas whose pressure is varied to increase and fine-tune thermal transport.

U.S. Patent Publication No. 2006/0144516A1 controls the temperature of a substrate by the use of adhesive materials, i.e., a first layer of adhesive material to bond the metal plate and the heater to the top surface of the temperature controlled base, and a second layer of adhesive material bonds the layer of dielectric material to a top surface of the metal plate. The adhesive possesses physical properties that allow the thermal pattern to be maintained under varying external process conditions.

There still exists a need for a heating apparatus providing relatively uniform temperature distribution to a substrate and a method for controlling the temperature of the substrate placed thereon, during processing of a wafer in semiconductor device fabrication and for other substrates in similar processes.

### SUMMARY

The following presents a summary of this disclosure to provide a basic understanding of some aspects. This summary is intended to neither identify key or critical elements nor define any limitations of embodiments or claims. Furthermore, this summary may provide a simplified overview of some aspects that may be described in greater detail in other portions of this disclosure.

Provided is a heater assembly suitable for controlling or providing substantially uniform temperature distribution over the heating surface. The heater assembly includes a top plate and a bottom plate comprising a heating element. In particular, it has been found that the temperature distribution of the heating surface can be configured and controlled by controlling the point of contact between the top plate and the bottom plate. In accordance with aspects herein, the points of contact between the top plate and the bottom plate may be controlled by providing contact points and non-contact regions on a surface of the top plate or the bottom plate.

In one aspect, provided is a heating apparatus comprising: a bottom plate comprising a heating element, the base plate defining an upper surface; and a top plate disposed over the base plate, the top plate having (i) an upper surface to support a substrate to be heated, and (ii) a lower surface, wherein the upper surface of the bottom plate or the lower surface of the top plate comprises a surface topography defining a plurality of contact points and a plurality of non-contact areas with the other plate.

In one embodiment, the surface topography is defined by a plurality of projections extending from the bottom surface of the top plate.

In one embodiment, the plurality of projections are chosen from a cylinder, a cone, a pyramid, a truncated pyramid, a ring, or a combination of two or more thereof.

In one embodiment, the plurality of projections are chosen from a plurality of rings. In one embodiment, the rings each have a different circumference, and the rings are disposed in a nested arrangement, the non-contact areas defined by the space between adjacent rings. In one embodiment, the rings are in the shape of a triangle, a circle, an ellipse, a rectangle, a pentagon, a hexagon, a heptagon, or an octagon. In one embodiment, the surface comprises 2-20 rings.

In one embodiment of the heating apparatus according to any previous embodiment, the bottom plate further comprises a thermally conductive material disposed therein. In one embodiment, the insert is chosen from a graphite material. In one embodiment, the graphite material is chosen from a thermal pyrolytic graphite material. In one embodiment, the thermal pyrolytic graphite material is metalized on its surfaces.

In one embodiment of the heating apparatus according to any previous embodiment, a thermally conductive material is disposed in at least a portion of the non-contact regions.

In one embodiment of the heating apparatus according to any previous embodiment, the top plate and the bottom plate are formed from a material independently chosen from a metal, a metal alloy, or a ceramic material.

In one embodiment of the heating apparatus according to any previous embodiment, the top plate and the bottom plate are formed from a metal chosen from aluminum, iron, copper, nickel, titanium, indium, magnesium, tin, silver, or zinc.

In another aspect, provided is a method of making a heating apparatus of any previous aspect or embodiment. In one embodiment, the method comprises associating (i) a top plate defining an upper surface for supporting a substrate and a lower surface with (ii) a bottom plate having an upper surface and a heating element disposed within the top plate, wherein a surface interface is provided between the top plate and the bottom plate defining a plurality of contact points and non-contact areas.

In one embodiment, the surface topography is provided by machining, etching, or stamping.

In one embodiment, the top plate and the bottom plate are mechanically fastened to one another.

In one embodiment, the contact points and the non-contact areas are provided by providing the upper surface of the bottom plate with a brazing material; providing the lower surface of the top plate with a plurality of projections; and heating the unit so as to cause the plurality of projections to bond with the upper surface of the top plate.

In still another aspect, provided is a heating apparatus comprising:

a bottom plate comprising a heating element, the bottom plate being formed from an aluminum material and defining an upper surface and comprising a thermal conducting material; and

a top plate disposed over the bottom plate, the top plate being formed from an aluminum material and having (i) an upper surface to support a substrate to be heated, and (ii) a lower surface, wherein the lower surface of the top plate comprises a surface topography defined by a plurality of projections, the projections being arranged in a series of concentric rings extending radially from the center of the heating apparatus.

The following description and the drawings disclose various illustrative aspects. Some improvements and novel aspects may be expressly identified, while others may be apparent from the description and drawings.

### BRIEF DESCRIPTION OF THE DRAWINGS

The accompanying drawings illustrate various systems, apparatuses, devices and related methods, in which like reference characters refer to like parts throughout, and in which:

FIG. 1 is a cross-sectional view of a heater assembly in accordance with an embodiment disclosed herein;

FIG. 2A is a bottom view of a top plate of a heater assembly in accordance with an embodiment disclosed herein;

FIG. 2B is a cross-section view of a heater assembly employing the top plate of FIG. 2A;

FIG. 3A is a bottom view of a top plate of a heater assembly in accordance with an embodiment disclosed herein;

FIG. 3B is a cross-sectional view of a heater assembly employing the top plate of FIG. 3A;

FIG. 3C is a cross-sectional view of a heater assembly employing an alternate embodiment the top plate of FIG. 3A with projections of a different shape;

FIG. 4A is a bottom view of a top plate for a heater assembly in accordance with an embodiment disclosed herein;

FIG. 4B is a cross-sectional view of a heater assembly employing the top plate of FIG. 4A;

FIG. 5A is a bottom view of a top plate for a heater assembly in accordance with an embodiment disclosed herein;

FIG. 5B is a cross-sectional view of a heater assembly employing the top plate of FIG. 6A;

FIG. 6A is a bottom view of a top plate for a heater assembly in accordance with an embodiment disclosed herein;

FIG. 6B is a cross-sectional view of a heater assembly employing the top plate of FIG. 6A;

FIG. 7A is a bottom view of a top plate of for a heater assembly in accordance with an embodiment disclosed herein;

FIG. 7B is a cross-sectional view of a heater assembly employing the top plate of FIG. 3A;

FIG. 7C is a cross-sectional view of a heater assembly employing an alternate embodiment the top plate of FIG. 3A;

FIGS. 8A-8C are cross-sectional views showing aspects of forming a heater assembly in accordance with an embodiment disclosed herein;

FIGS. 9A and 9B are temperature heating profiles for a heater assembly described in Control 1 of the Examples;

FIGS. 10A and 10B are temperature heating profiles for a heater assembly for a heater assembly described in Control 1 of the Examples;

FIG. 11 is a bottom view of a top plate in Example 1;

FIGS. 12A and 12B are temperature profiles for a heater assembly employing the top plate of Example 1;

FIG. 13 is a bottom vie of a top plate in Example 2; and

FIGS. 14A and 14B are temperature profiles for a heater assembly employing the top plate of Example 2.

### DETAILED DESCRIPTION

Reference will now be made to exemplary embodiments, examples of which are illustrated in the accompanying drawings. It is to be understood that other embodiments may be utilized and structural and functional changes may be made. Moreover, features of the various embodiments may be combined or altered. As such, the following description is presented by way of illustration only and should not limit in any way the various alternatives and modifications that may be made to the illustrated embodiments. In this disclosure, numerous specific details provide a thorough understanding of the subject disclosure. It should be understood that aspects of this disclosure may be practiced with other embodiments not necessarily including all aspects described herein, etc.

As used herein, the words “example” and “exemplary” mean an instance, or illustration. The words “example” or “exemplary” do not indicate a key or preferred aspect or embodiment. The word “or” is intended to be inclusive rather than exclusive, unless context suggests otherwise. As an example, the phrase “A employs B or C,” includes any inclusive permutation (e.g., A employs B; A employs C; or A employs both B and C). As another matter, the articles “a” and “an” are generally intended to mean “one or more” unless context suggest otherwise.

As used herein, the terms “heating apparatus” and “heater assembly” may be used interchangeably with “treating apparatus,” “heater,” “electrostatic chuck,” “chuck,” or “processing apparatus,” referring to an apparatus containing at least one heating and/or cooling element to regulate the temperature of the substrate supported thereon, specifically, by heating or cooling the substrate.

As used herein, the term “substrate” refers to any substrate of interest including, but not limited to, a semiconductor wafer, a glass mold, etc., being supported/heated by the processing apparatus of the invention. As used herein, the term “sheet” may be used interchangeably with “layer.”

As used herein, the term “circuit” may be used interchangeably with “electrode,” and the term “heating element” may be used interchangeably with “heating electrode,” “electrode,” “resistor,” “heating resistor,” or “heater.” The term “circuit” may be used in either the single or plural form, denoting that at least one unit is present.

Provided is a heater assembly adapted to provide more uniform temperature distribution to the heating surface. In particular, a heater assembly is provided having a bottom plate comprising one or more heating elements, and a top plate disposed on the bottom plate, the top plate defining an upper surface for supporting a substrate to be heated, where at least one of the top plate or the bottom plate is configured such that contact points between the lower surface of the upper plate and the lower plate have been reduced or limited. The contact points between the top plate and the bottom plate are limited by controlling (i) the topography of the bottom surface of the top plate that is adjacent to and/or contacts the bottom plate, or (ii) the topography of the upper surface of the bottom plate that is adjacent to and/or contacts the bottom plate. The topography of the lower surface of the top plate or the upper surface of the top plate is configured to provide a plurality of contact points and a plurality of non-contact regions between the top plate and the bottom plate.

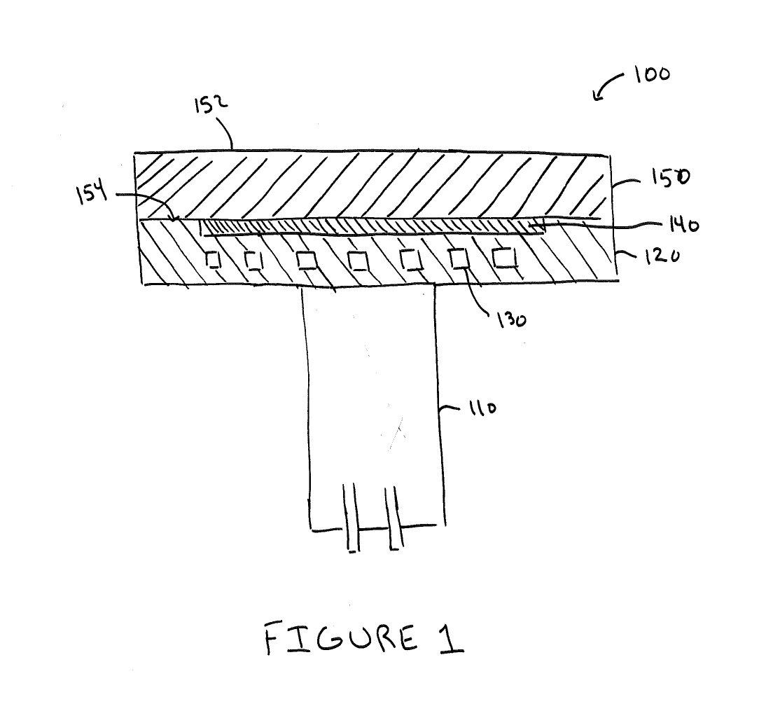

Referring to FIG. 1, a heater assembly 100 is illustrated. The heater assembly 100 includes a shaft 110, and a heater body 120. The heater body 120 includes heating elements 130 disposed within the heater body 120. The heater body 120 defines an upper surface 152. In the embodiment of FIG. 1, the heater assembly is shown as comprising an insert 140 disposed within the heater body 120. As shown in FIG. 1, the insert 140 is disposed within a recess of the heater body 120 and provides a surface that is substantially co-planar with the upper surface of the heater body. In the embodiment of FIG. 1 or similar embodiments where the insert provides a surface that is substantially co-planar with the upper surface of the heater body, reference to the upper surface of the heater body will include the upper surface defined by the insert. The heater body 120 may also be referred to herein as bottom plate. The insert 140 may be, for example, a heat spreader material such as, for example, thermal pyrolytic graphite. Thermal pyrolytic graphite may serve the function of spreading heat radially outward toward the edges of the heater assembly. In another embodiment, the insert may be embedded within (i.e., below the surface of) bottom plate. It will also be appreciated that the heater need not include an insert.

The heater assembly 100 further includes a top plate 150 disposed over the heater body 120. The top plate defines 150 defines a top surface 152 for supporting a substrate to be heated, and a bottom surface 154 in contact with the upper surface of the heater body. In accordance with aspects of the invention, the bottom surface 154 of the upper plate 150 has a surface topography providing limited contact points between the bottom surface 154 of the upper plate 150 and the upper surface 122 of the bottom plate 120.

The surface topography of the bottom surface of the upper plate or the upper surface of the bottom plate may be provided or configured in any suitable manner that provides a reduced or limited contact area (relative to a substantially planer or flat surface) between the bottom surface of the upper plate and the upper surface of the bottom plate. This may generally be provided by providing a plurality of recessed areas on the lower surface of the top plate or the upper surface of the bottom plate.

In embodiments, the reduced contact points of the lower surface of the top plate may be provided by providing the lower surface of the top plate or the upper surface of the bottom plate with a topography defined by a plurality of shaped projections. The apex or bottom most surface of the projections defines the surface of the top plate that will contact the bottom plate, and the recessed areas, spaces, or regions between the projections define the non-contact regions. The shapes of the projections are not particularly limited and can be chosen as desired for a particular purpose or intended application. Examples of suitable shapes for the projections include, but are not limited to hemispherical, cylinder, conical, pyramid, truncated pyramid, or a combination of two or more thereof. It will be appreciated that cylinder projections may define a substantially flat surface, and the cylinder, and the circumference of the cylinder may be in the form of any suitable geometric shape including, but not limited to, elliptical, circular, triangle, rectangle, square (cubic), pentagonal, hexagonal, heptagonal, octagonal, etc.

The projections may be arranged in a random array or a regular array as may be desired. In one embodiment, the projections may be provided as a plurality of discrete structures defining a pattern or a non-random array. In another embodiment, a projection may be an elongated or substantially continuous structure arranged in a geometric pattern extending about the surface of the plate. In one embodiment, the projections may be extended or elongated projections disposed in parallel to one another. In embodiments, the elongated projection may be disposed on the surface as a pattern or geometric pattern on the surface such as in the pattern of a circle, ellipse, rectangle, square, triangle, pentagon, hexagon, a spiral, a wave, a zig-zap pattern, etc. The shape of the projection itself that is arranged in a pattern or geometric pattern may have any shape as described above including, but not limited to, cubic, pyramid, truncated pyramid, hemispherical, etc. In embodiments, the topography is provided by a plurality of substantially continuous projections arranged as a plurality of concentric geometric shapes (e.g., concentric circles, squares, triangles, etc.). When the projections are elongated projections extending in a concentric geometric shape, a plurality of projections may be employed of different circumferences, and the shapes can be “nested” within one another to define the surface.

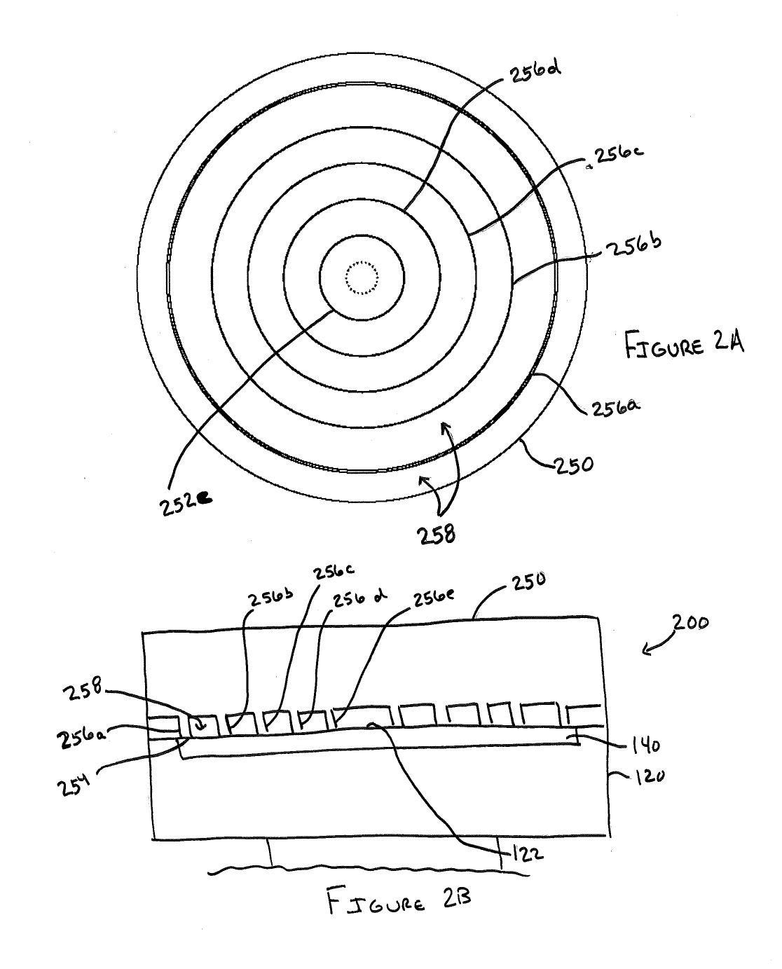

FIGS. 2A and 2B show an embodiment of a top plate (FIG. 2A) having a surface topography provided by a plurality of projections, and a heater assembly (FIG. 2B) employing such a top plate. The top plate comprises a plurality of continuous projections (256a-256e) arranged as concentric circles or rings on the top plate. The projections define a surface that contacts the upper surface 122 of the bottom plate 120 with recessed areas 258 defining the non-contact regions (FIG. 2B). As used herein, the upper plate 120 includes and is defined by the upper surface of the bottom plate and, if applicable, the exposed surface of the insert (e.g., the exposed surface of insert 140).

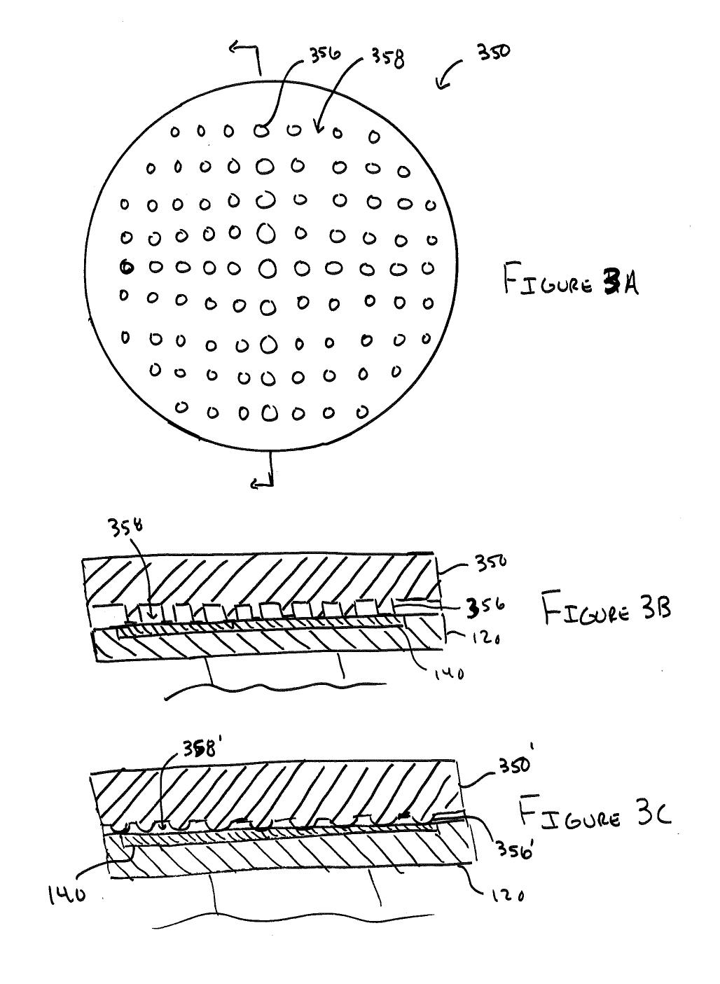

FIGS. 3A-3C illustrate another embodiment employing a plurality of projections to provide a top plate with a reduced contact between the top plate and the bottom plate. The bottom surface of the top plate 350 includes a plurality of projections 356 and non-contact regions 358 defined between the projections. In the embodiment in FIG. 3A, the projections are arranged in a regular array of ordered rows. In order to control the heat flow to the top surface, the size and spacing can vary, and may be optimized to achieve uniform temperature on the wafer. FIG. 3A shows a bottom view of the top plate 350. In this view, the circumference of the projections are illustrated as circular. FIGS. 3B and 3C illustrate alternative shapes of the projections. In FIG. 3B, the projections 356 are illustrated as being cylinders. In FIG. 3C, the projections 356′ are illustrated as hemispheres.

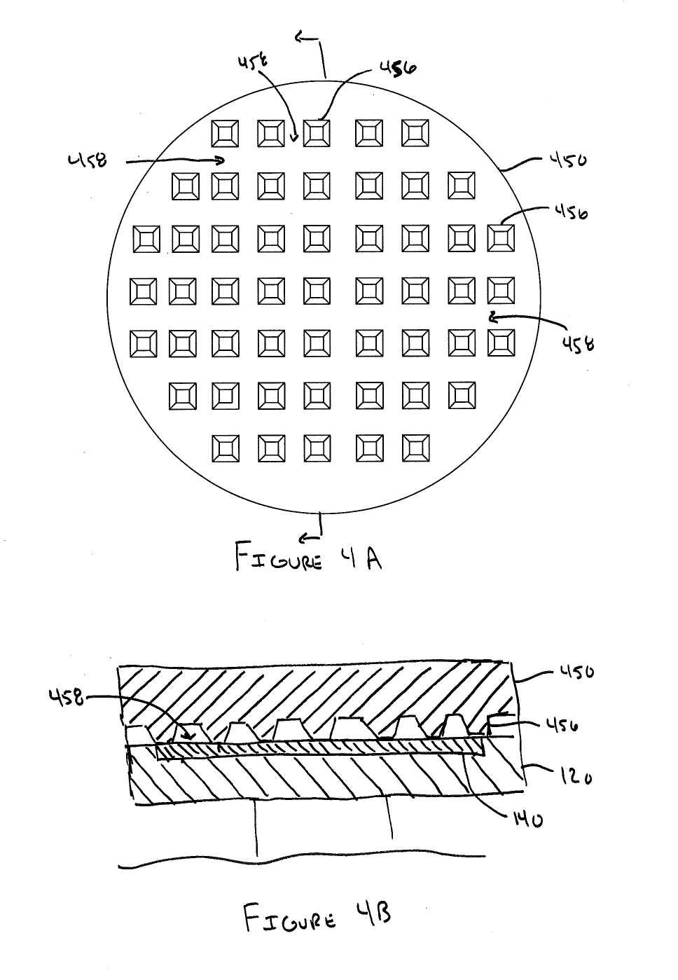

FIGS. 4A and 4B illustrate an embodiment of a top plate 450 employing projections 456 having a truncated pyramid shape. The projections 456 are arranged in a regular array of ordered rows with non-contact regions 458 defined by the recessed areas between the projections. The truncated portion of the projections 456 define the point of contact with the bottom plate (e.g., bottom plate 120).

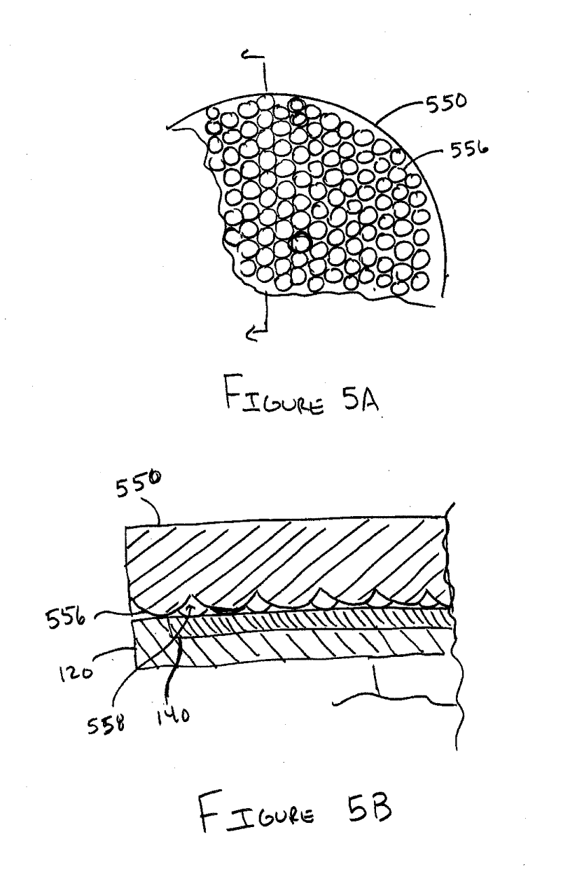

FIGS. 5A and 5B illustrate an embodiment of a top plate 550 employing hemispherical projections 556. The projections 556 are provided and arranged such that the projections are closely spaced to define the surface topography. The apex of the hemispherical projections provides the contact point for the upper plate with the surface of the bottom plate. The non-contact regions are the recessed areas between adjacent projections.

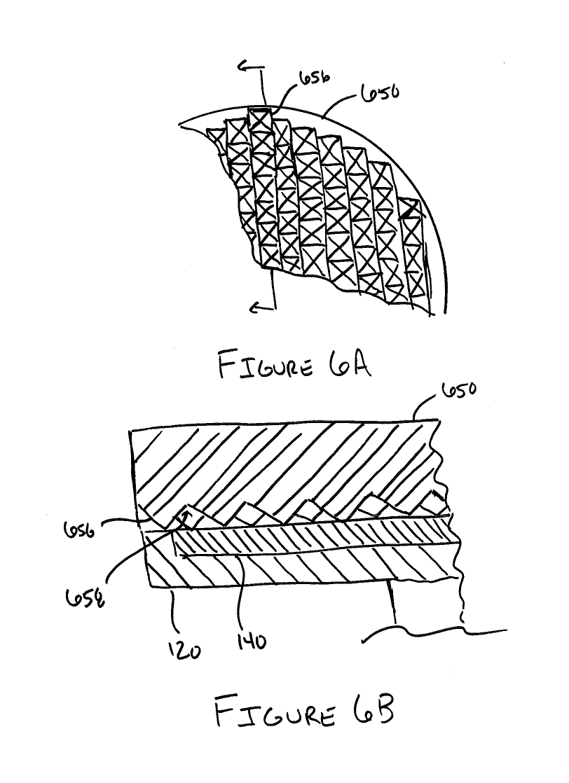

FIG. 6A shows a bottom view of a portion or section of a top plate 650 with a plurality of projections 656 defining the topography of the lower surface of the top plate 650. Projections 656 are discrete pyramid shaped projections covering substantially the entire bottom surface of the top plate 650. The shape of the projection defines the non-contact regions. FIG. 6B shows a cross-sectional view of a portion of a heater apparatus employing the top plate 650, where the top plate 650 contacts bottom plate 120.

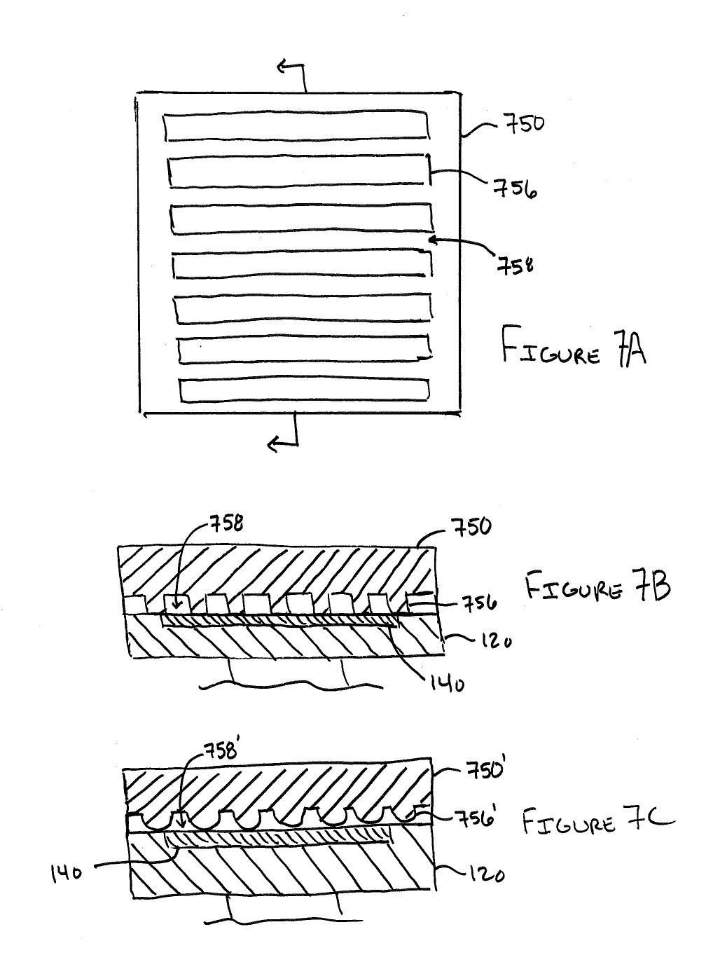

FIG. 7A is a bottom view of a top plate 750 comprising a plurality of projections 756. The projections 756 are elongated members disposed parallel to one another, and non-contact regions 758 are provided in the regions surrounding and adjacent the elongated members. FIGS. 7B and 7C show cross-sectional views of a heater apparatus comprising the top plate 750. FIGS. 7B and 7C illustrate different shapes of the projections 756 and 756′ defining non-contact regions 758 and 758′.

It will be appreciated that the size, shape, height, number, spacing, and arrangement of the projections is not particularly limited and may be chosen as desired for a particular purpose or intended application. For example, in embodiments where the projections are arranged as concentric shapes (e.g., concentric circles or rings as illustrated in FIG. 2A), the thickness of the projections, the height of the projection, the spacing between the projections, and the number of projections may be selected as desired. Controlling the number and spacing of the projections will allow for control of the temperature distribution of the heating assembly. The size of the projections is not particularly limited and may be chosen as desired for a particular purpose or intended application. The depth of the projections is also not particularly limited and may be chosen as desired for a particular purpose or intended application. In embodiments, the depth or height (h) of the projections may be from about 0.2 mm to about 10 mm; from about 0.5 mm to about 5 mm; even from about 1 mm to about 3 mm.

While the figures illustrate embodiments wherein the lower surface of the top plate is configured with a surface topography to limit the points of contact with the bottom plate, a heater apparatus is not limited in this manner. As previously described, the upper surface of the bottom plate may be provided with a surface topography to limit the points of contact with the top plate. Additionally, the shape of the top plate is generally not limited. The figures generally illustrate the top plate having a circular shape. It will be appreciated that the circumference of the top plate and the bottom plate may be any shape as desired including rectangular, square, triangular, pentagonal, hexagonal, etc.

Further, a thermal conducting material may be disposed at the interface between the bottom plate and the top plate (defined by the contact points between the projections of one plate and the surface of the other plate) to ensure low thermal conductance between the surface of the projections and the surface of the plate that the projections contact. The thermal conducting material may be, for example, a graphite material (including those further described herein), a brazing material, a soft aluminum material, or a metalized graphite material.

The top plate and the bottom plate of the heater assembly may be formed from any suitable material as desired for a particular purpose or intended application. In one embodiment, the top plate and/or bottom plate may be formed of a metal or alloy having high thermal conductivity. The material of the top plate and/or bottom plate may be selected on the basis of an operating temperature range of the shaft-equipped heater assembly. Suitable materials include, for example, aluminum or aluminum alloy, iron or iron alloy, copper or copper alloy, nickel or nickel alloy, titanium or titanium alloy, indium, lead, magnesium, tin, silver, and zinc, etc.

Still other suitable materials for the upper plate and the lower plate include ceramic materials. Examples of suitable ceramic materials include, but are not limited to, oxides, nitrides, carbides, carbonitrides, and oxynitrides of elements selected from a group consisting of B, Al, Si, Ga, Y, refractory hard metals, transition metals; and combinations thereof. In one embodiment, the material for the upper plate and the lower plate comprises AlN of >99.7% purity and a sintering agent selected from Y₂O₃, Er₂O₃, and combinations thereof.

The shape of the heater assembly is not particularly limited and may be selected as desired for a desired purpose or intended application. While the shape of the top plate and the bottom plate are generally shown as circular in many of the figures, it will be appreciated that the top plate and the bottom plate may have any suitable shape (defining the circumference of the respective plates) including, but not limited to, a square, a rectangle, a triangle, a diamond, a trapezoid, a pentagon, hexagon, a heptagon, an octagon, etc.

The projections and topography of the lower surface of the top plate or the upper surface of the bottom plate may be formed in any suitable manner. The surface topography may be formed, for example, by machining, stamping, etching, etc., a surface topography into the surface of the desired piece. In one embodiment, a top plate or a bottom plate is provided with a pre-formed surface topography. The top plate and the bottom plate (at least one of which comprises a surface with a desired surface topography) may then be mated with the other piece and held together by any suitable fastener including, but not limited to, a clamp, bolt, screw, pin, etc.

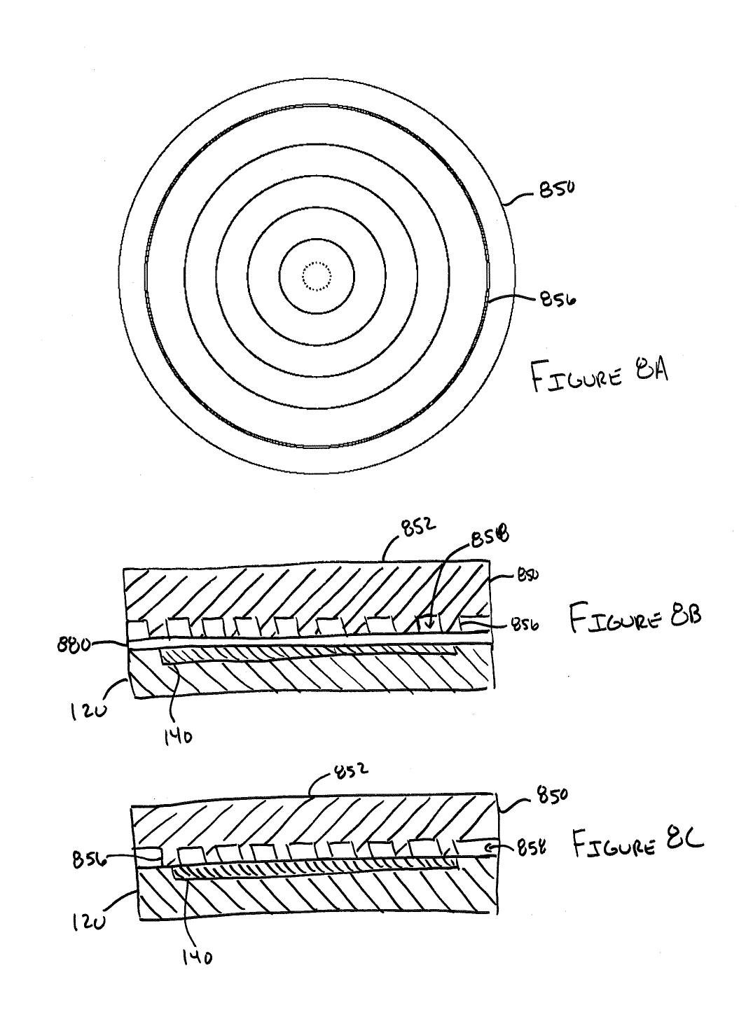

In one embodiment, the surface topography and contact points of the top plate may be formed by brazing of the top plate with the bottom plate. FIGS. 8A-8C illustrate aspects of forming the heater apparatus in this manner. A top plate 850 and a bottom plate 120 are provided. The top plate 850 has an upper surface 850 for supporting a substrate to be heated, and a lower surface 854. The lower surface 854 defines a plurality of projections 856. A sheet of thin brazing material 880 is placed on the top surface of the bottom plate 120 (FIG. 8B). The unit is heated to a temperature sufficient to flow the brazing material, and a bond forms between the projections of the top plate and the bottom plate (and the insert 140 if employed in the heater) in the regions defined by the projections (FIG. 8C), which defines the contact points between the top plate and the bottom plate.

The thickness of the brazing material foil may be from about 0.01 mm to about 1 mm; from about 0.02 mm to about 0.5 mm; even from about 0.025 mm to about 0.15 mm. Generally, the thickness of the brazing material should be less than the height of the projections so that the brazing material does not fill the recessed areas and substantially reduce the non-contact regions defined between the projections.

In embodiments employing an insert to aid in thermal conductivity and heat dispersion, the insert (e.g., insert 140) may be chosen from any suitable material to assist with heat dispersion. In one embodiment, the insert is a graphite material. Graphite is an anisotropic material with a unique ability to direct heat in a preferred direction. Thermal pyrolytic graphite (TPG) is a unique graphite material consisting of crystallites of considerable size, the crystallites being highly aligned or oriented with respect to each other and having well ordered carbon layers or a high degree of preferred crystallite orientation. TPG may be may be used interchangeably with “highly oriented pyrolytic graphite” (“HOPG”), or compression annealed pyrolytic graphite (“CAPG”). TPG is extremely thermally conductive with an in-plane (a-b direction) thermal conductivity greater than 1000 W/m-K, while the thermal conductivity in the out-of-plane (z-direction) is in the range of 20 to 30 W/m-K. In one embodiment, TPG has an in-plane thermal conductivity greater than 1,500 W/m-K.

In various embodiments of the heater apparatus, at least a layer of TPG is provided in the heater to provide spatial control of the surface temperature of the substrate and diffuse the temperature difference of the various components in the heating apparatus, allowing the temperature of the target substrate to be relatively uniform even for heating element with an imperfect, e.g., uneven, contact surface. In operations, a semiconductor wafer substrate or a glass mold is typically heated to a temperature of at least 300° C. and then cooled down to room temperature. The heating apparatus with at least an embedded layer of TPG provides effective heat conduction/cooling between a heating/cooling element and a substrate with excellent thermal uniformity.

In one embodiment, the TPG layer has a thickness ranging from about 0.5 mm to 15 mm (with thickness variation (parallelism) within 0.005 mm); 1 mm to 10 mm; even 2 to 8 mm. The TPG layer may be embedded in the heater of the invention as a single layer by itself, or in one embodiment for a heater with a metal substrate, the TPG layer can be in an encapsulated form, e.g., a TPG core encapsulated within a structural metallic shell. Encapsulated TPG is commercially available from Momentive Performance Materials Inc. as TC1050® encapsulated TPG. TPG can be incorporated into the heater as a contiguous single sheet, or in one embodiment, a plurality of smaller TPG pieces in an overlapping/mosaic configuration.

In one embodiment, the TPG is held in place and embedded within the heater simply by the adhesion of the underlying substrate and/or overcoat where they make contact. In another embodiment, the TPG (in a pure TPG sheet form, or as an encapsulated TPG core in a metal casing, as pure thermal pyrolytic graphite in small piece sizes such as rectangular, square pieces; in random sizes; or in “strips”) is glued in place using a high-temperature adhesive known in the art, e.g., CERAMBOND™ from Aremco, a silicone bond having a thermal transfer coefficient.

The heating element (e.g., heating element 130) may be provided by any suitable material. The heating element may be provided by one or more electrodes. Depending on the application, the electrode may function as a resistive heating element, a plasma-generating electrode, an electrostatic chuck electrode, or an electron-beam electrode. The electrode can be embedded within the substrate of the heater toward the top (near the wafer substrate) or the bottom (away from the wafer substrate). The heating element, may be, for example, a nichrome wire, and an insulator formed by solidification of powder such as magnesia powder on the outer periphery of the resistance heating element, and supplies electric power to the resistance heating element to generate heat. In one embodiment, the electrode is in the form of a film electrode and formed by processes known in the art including screen-printing, spin coating, plasma spray, spray pyrolysis, reactive spray deposition, sol-gel, combustion torch, electric arc, ion plating, ion implantation, sputtering deposition, laser ablation, evaporation, electroplating, and laser surface alloying. In one embodiment, the film electrode comprises a metal having a high melting point, e.g., tungsten, molybdenum, rhenium, platinum, or alloys thereof. In another embodiment, the film electrode comprises at least one of carbides or oxides of hafnium, zirconium, cerium, or mixtures of two or more thereof.

In another embodiment, the electrode layer is in the form of an elongated continuous strip of pyrolytic graphite. Pyrolytic graphite (“PG”) is first deposited onto a heater base, e.g., pyrolytic boron nitride coated graphite base, via processes known in the art such as chemical vapor deposition. The PG is then is machined into a pre-determined pattern, e.g., a spiral, a serpentine, etc. The forming of the electrical pattern of the heating zones, i.e., an electrically isolated, resistive heater path, may be done by techniques known in the art, including but not limited to micro machining, micro-brading, laser cutting, chemical etching, or e-beam etching.

The heater of the invention can be used in a number of different processes, including plasma-etching chamber for processing glass molds, or in semiconductor processing chambers including but not limited to atomic layer epitaxy (ALD), low pressure CVD (LPCVD), and plasma-enhanced CVD (PECVD).

What has been described above includes examples of the present specification. It is, of course, not possible to describe every conceivable combination of components or methodologies for purposes of describing the present specification, but one of ordinary skill in the art may recognize that many further combinations and permutations of the present specification are possible. Accordingly, the present specification is intended to embrace all such alterations, modifications and variations that fall within the spirit and scope of the appended claims. Furthermore, to the extent that the term “includes” is used in either the detailed description or the claims, such term is intended to be inclusive in a manner similar to the term “comprising” as “comprising” is interpreted when employed as a transitional word in a claim.

### EXAMPLES

Aspects of this disclosure will now be described and may be further understood with respect to the following examples. The examples are intended to be illustrative only and are to be understood as not limiting the invention disclosed herein in any way as to materials, or process parameters, equipment or conditions.

Control 1

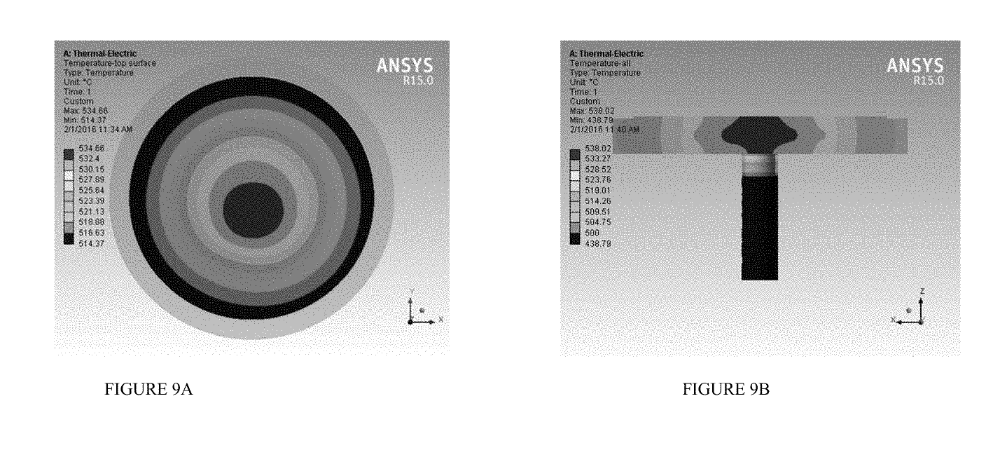

A heating apparatus is provided with an aluminum top plate and an aluminum bottom plate wherein the top plate is not contoured and the entire lower surface of the top plate is in contact with the top surface of the bottom plate. The power input is about 1.5 kW and the surface emissivity is about 0.3. FIGS. 9A and 9B show a temperature profile of the apparatus.

Control 2

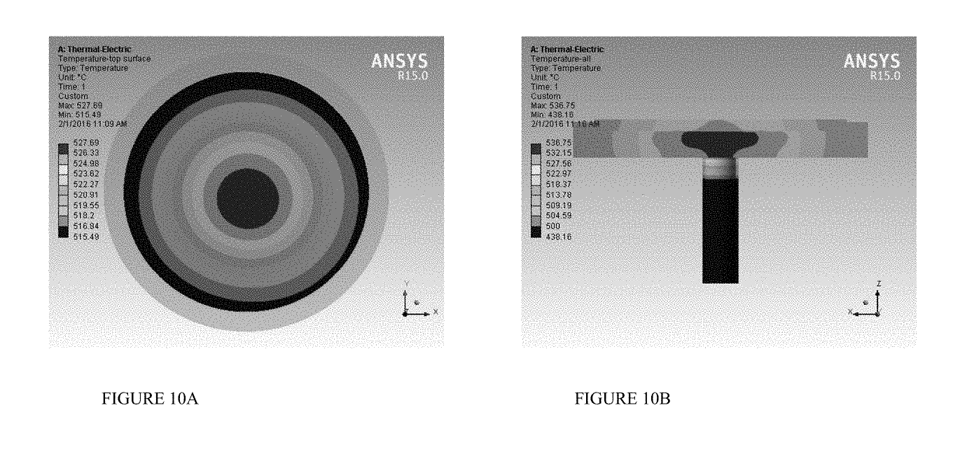

A heating apparatus is provided with an aluminum top plate and an aluminum bottom plate. The bottom plate includes a 2 mm TPG plate. The top plate has a substantially flat bottom surface and the entire lower surface of the top plate is in contact with the upper surface of the bottom plate (defined by the upper surface of the bottom plate and the upper surface of the TPG plate). The heating element is embedded in the bottom plate as illustrated in FIG. 1. Those values are for all samples for demonstration purpose only. FIGS. 10A and 10B show a temperature profile of the heating apparatus. With the TPG plate, the heating apparatus has a temperature reduction of 39.9% compared to the assembly of Control 1.

### Example 1

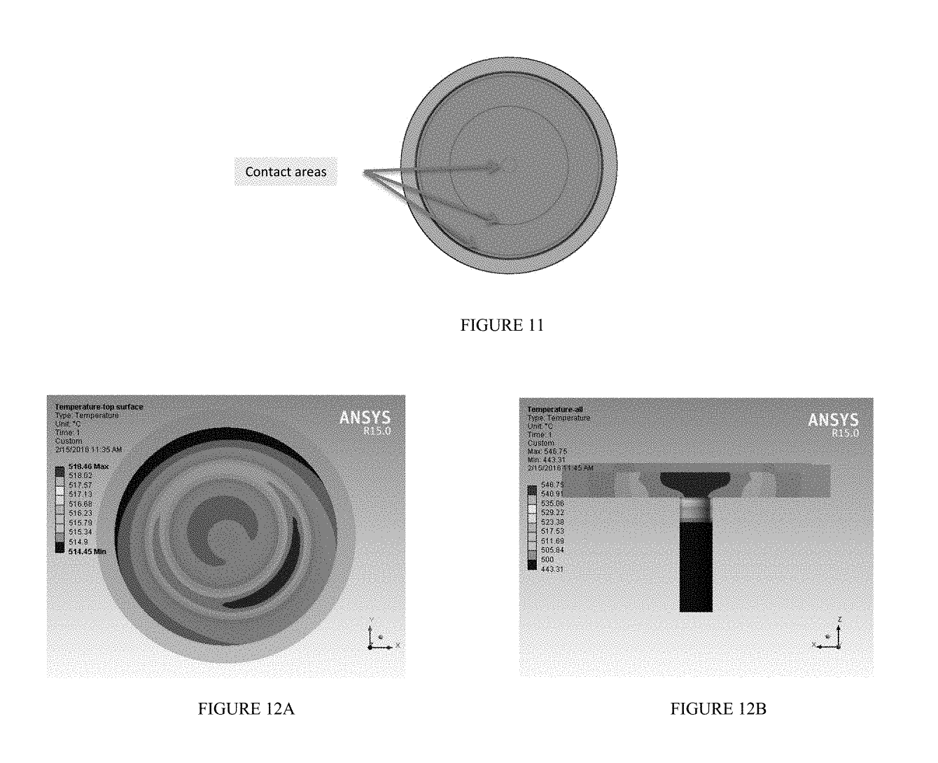

A heating apparatus is provided with an aluminum top plate and an aluminum bottom plate. The top plate is configured with three projections provided as concentric rings. The rings have a thickness of 0.5 mm and a height of 0.25 mm, and are spaced at 12 mm, 96 mm, and 145 mm, from the center of the plate. (FIG. 11). All the boundary conditions remain the same. FIGS. 12A and 12B show a temperature profile of the heating apparatus of Example 1. The heating apparatus has a temperature reduction of 80.2% compared to the temperature of the heating apparatus of Control 1.

### Example 2

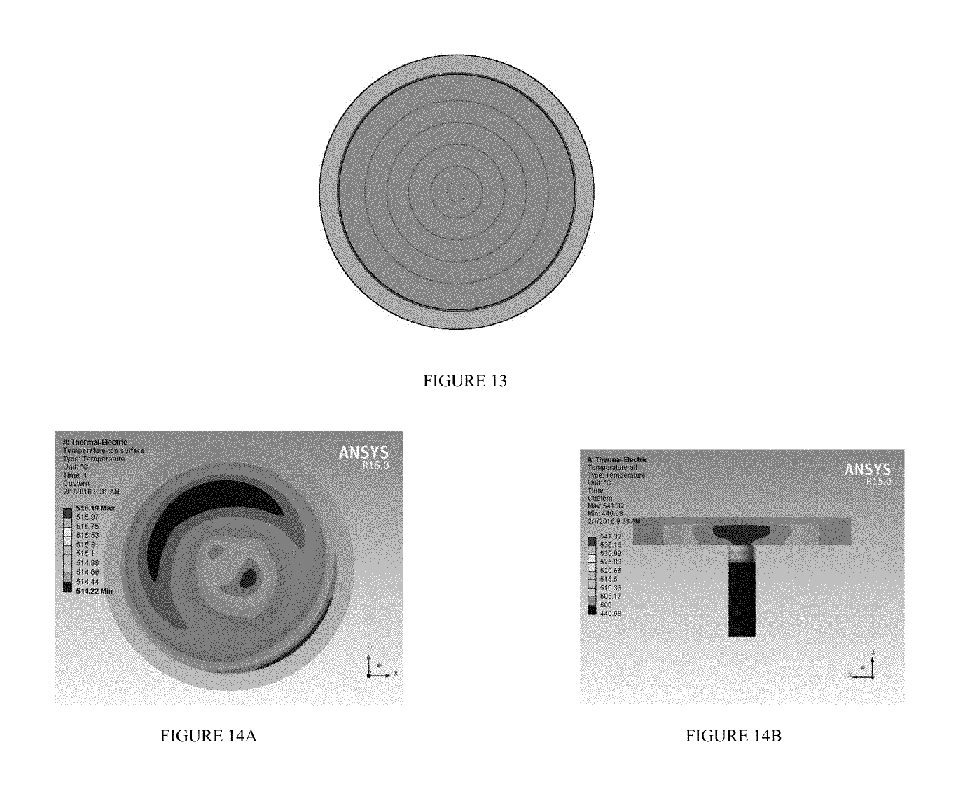

A heating apparatus is provided with an aluminum top plate and an aluminum bottom plate. A 2 mm TPG plate is provided in the upper surface of the bottom plate. The top plate is configured with five projections provided as concentric rings. The rings have a thickness of 0.5 mm and a height of 0.25 mm, and are spaced at 12 mm, 33 mm, 61 mm, 89 mm, and 117 mm, from the center of the plate. (FIG. 13). All the boundary conditions remain the same. FIGS. 14A and 14B show a temperature profile of the heater assembly of Example 2. The heater assembly has a temperature reduction of 90.3% compared to the temperature of the heating apparatus of Control 1.

The foregoing description identifies various non-limiting embodiments of a heater assembly. Modifications may occur to those skilled in the art and to those who may make and use the invention. The disclosed embodiments are merely for illustrative purposes and not intended to limit the scope of the invention or the subject matter set forth in the claims.

What is claimed is:

1. A heating apparatus comprising:
a bottom plate comprising a heating element, the base plate defining an upper surface; and
a top plate disposed over the base plate, the top plate having (i) an upper surface to support a substrate to be heated, and (ii) a lower surface, wherein the upper surface of the bottom plate or the lower surface of the top plate comprises a surface topography defining a plurality of contact points and a plurality of non-contact areas with the other plate.

2. The heating apparatus of claim 1, wherein the surface topography is defined by a plurality of projections extending from the bottom surface of the top plate.

3. The heating apparatus of claim 2, wherein the plurality of projections are chosen from a cylinder, a cone, a pyramid, a truncated pyramid, a ring, or a combination of two or more thereof.

4. The heating apparatus of claim 3, wherein the plurality of projections are chosen from a plurality of rings.

5. The heating apparatus of claim 4, wherein the rings each have a different circumference, and the rings are disposed in a nested arrangement, the non-contact areas defined by the space between adjacent rings.

6. The heating apparatus of claim 5, wherein the rings are in the shape of a triangle, a circle, an ellipse, a rectangle, a pentagon, a hexagon, a heptagon, or an octagon.

7. The apparatus of claim 4, wherein the rings are in the shape of the circle.

8. The apparatus of claim 4, comprising 2-20 rings.

9. The apparatus of claim 1, wherein the bottom plate further comprises a thermally conductive material disposed therein.

10. The apparatus of claim 9, wherein the insert is chosen from a graphite material.

11. The apparatus of claim 9, wherein the graphite material is chosen from a thermal pyrolytic graphite material.

12. The apparatus of claim 11, wherein the thermal pyrolytic graphite material is metalized on its surfaces.

13. The apparatus of claim 1 further comprising a thermally conductive material disposed in at least a portion of the non-contact regions.

14. The apparatus of claim 1, wherein the top plate and the bottom plate are formed from a material independently chosen from a metal, a metal alloy, or a ceramic material.

15. The apparatus of claim 14, wherein the top plate and the bottom plate are formed from a metal chosen from aluminum, iron, copper, nickel, titanium, indium, magnesium, tin, silver, or zinc.

16. A method of making a heater apparatus comprising:
associating (i) a top plate defining an upper surface for supporting a substrate and a lower surface with (ii) a bottom plate having an upper surface and a heating element disposed within the top plate, wherein a surface interface is provided between the top plate and the bottom plate defining a plurality of contact points and non-contact areas.

17. The method of claim 16, wherein the plurality of contact points and non-contact areas are provided by a surface topography defined on the lower surface of the top plate or the upper surface of the bottom plate.

18. The method of claim 17, wherein the surface topography is defined by a plurality of projections.

19. The method of claim 16, wherein the surface topography is provided by machining, etching, or stamping.

20. The method of claim 16, wherein the top plate and the bottom plate are mechanically fastened to one another.

21. The method of claim 16, wherein the contact points and the non-contact areas are provided by:
providing the upper surface of the bottom plate with a brazing material;
providing the lower surface of the top plate with a plurality of projections; and
heating the unit so as to cause the plurality of projections to bond with the upper surface of the top plate.

22. The method of claim 16, wherein the bottom plate and the top plate comprise a metal chosen from aluminum, iron, copper, nickel, titanium, indium, magnesium, tin, silver, or zinc.

23. A heating apparatus comprising:
a bottom plate comprising a heating element, the bottom plate being formed from an aluminum material and defining an upper surface and comprising a thermal conducting material; and
a top plate disposed over the bottom plate, the top plate being formed from an aluminum material and having (i) an upper surface to support a substrate to be heated, and (ii) a lower surface, wherein the lower surface of the top plate comprises a surface topography defined by a plurality of projections, the projections being arranged in a series of concentric rings extending radially from the center of the heating apparatus.
